(19) United States
(12) Patent Application Publication
(10) Pub. No.: US 2025/0141180 A1
(43) Pub. Date: May 1, 2025

(54) OPTOELECTRONIC SEMICONDUCTOR COMPONENT AND OPTOELECTRONIC MODULE

(71) Applicant: ams-OSRAM International GmbH, Regensburg (DE)

(72) Inventors: Jörg Erich SORG, Regensburg (DE); Erik HEINEMANN, Regensburg (DE); André SOMERS, Obertraubling (DE); Thomas KIPPES, Neumarkt (DE)

(73) Assignee: ams-OSRAM International GmbH, Regensburg (DE)

(21) Appl. No.: 18/692,734

(22) PCT Filed: Aug. 18, 2022
(86) PCT No.: PCT/EP2022/073083

§ 371 Date: Mar. 15, 2024

(30) Foreign Application Priority Data
Sep. 17, 2021 (DE) 10 2021 124 129.4

(51) Int. Cl. H01S 5/024; H01S 5/026; H01S 5/042

(52) U.S. Cl. CPC H01S 5/02469; H01S 5/02476; H01S 5/026; H01S 5/04256

(57) ABSTRACT

The invention relates to an optoelectronic semiconductor component including a semiconductor body having a first region with a first conductivity, a second region with a second conductivity and an active region which is designed to emit coherent electromagnetic radiation. An optical resonator is formed along a resonator axis in the semiconductor body. The semiconductor body has a mounting side and side surfaces running transversely to the mounting side. Side surfaces running parallel to the resonator axis are covered by an electrically insulating passivation. A cooling layer which is designed to dissipate at least part of the power loss created in the semiconductor body during operation is arranged on a side of the passivation facing away from the semiconductor body. The invention also relates to an optoelectronic module.

### CROSS-REFERENCE TO RELATED APPLICATIONS

The present application is a national stage entry from International Application No. PCT/EP2022/073083, filed on Aug. 18, 2022, published as International Publication No. WO 2023/041283 A1 on Mar. 23, 2023, and claims priority to German Patent Application No. 10 2021 124 129.4, filed Sep. 17, 2021, the disclosures of all of which are hereby incorporated by reference in their entireties.

### FIELD

An optoelectronic semiconductor component and an optoelectronic module are disclosed. The optoelectronic semiconductor component and the optoelectronic module are configured in particular for generating electromagnetic radiation, for example light perceptible to the human eye.

### BACKGROUND

One task to be solved is to specify an optoelectronic semiconductor component which exhibits improved cooling.

A further task to be solved is to provide an optoelectronic module which exhibits improved cooling. The optoelectronic module comprises at least two optoelectronic semiconductor components.

The semiconductor component is configured in particular for emitting coherent electromagnetic radiation.

### SUMMARY

According to at least one embodiment, the optoelectronic semiconductor component comprises a semiconductor body having a first region of a first conductivity, a second region of a second conductivity and an active region which is configured to emit coherent electromagnetic radiation. The semiconductor body is, for example, a layer sequence of layers of a semiconductor material which are grown epitaxially in the stacking direction. The conductivity of the first region and the second region is adjusted, for example, by means of doping with impurity atoms of a certain conductivity. Preferably, the first conductivity differs from the second conductivity.

For example, the semiconductor body is formed with a III/V compound semiconductor material. A III/V compound semiconductor material has at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. Such a binary, ternary or quaternary compound may also have, for example, one or more dopants and additional components. Preferably, the semiconductor body is formed with GaN or an InGaAs.

According to at least one embodiment of the optoelectronic semiconductor component, an optical resonator is formed in the semiconductor body along a resonator axis. The optical resonator enables a circulation of electromagnetic radiation along the resonator axis. In particular, the optical resonator enables coherent emission of electromagnetic radiation.

According to at least one embodiment of the optoelectronic semiconductor component, the semiconductor body has a mounting side and side faces extending transversely to the mounting side. For example, the mounting side extends transversely to the stacking direction of the semiconductor body. The mounting side of the semiconductor body is configured in particular for attaching the semiconductor body to other components. Preferably, the mounting side is flat. In particular, the side faces of the semiconductor body run parallel to the stacking direction of the semiconductor body.

According to at least one embodiment of the optoelectronic semiconductor component, side faces running parallel to the resonator axis are covered by an electrically insulating passivation. The passivation is formed, for example, with a dielectric, in particular silicon nitride. The passivation is used to protect the side faces of the semiconductor body from harmful environmental influences, such as moisture. In particular, the side faces running parallel to the resonator axis are completely covered by the passivation. As a result, a pn junction of the semiconductor body can be covered laterally over the entire surface by the passivation. Preferably, an output coupling surface of the semiconductor body remains free of the passivation.

According to at least one embodiment of the optoelectronic semiconductor component, a cooling layer is arranged on a side of the passivation facing away from the semiconductor body, which is configured to dissipate at least part of the power loss generated in the semiconductor body during operation. Preferably, the cooling layer has a thickness of between 30 μm and 50 μm, particularly preferably between 70 μm and 100 μm. For example, the cooling layer is formed with one of the following materials: copper, silver, solder, thermally conductive polymer.

According to at least one embodiment, the optoelectronic semiconductor component comprises a semiconductor body having a first region of a first conductivity, a second region of a second conductivity and an active region configured to emit coherent electromagnetic radiation, wherein
an optical resonator is formed in the semiconductor body along a resonator axis,
the semiconductor body has a mounting side and side faces extending transversely to the mounting side,
side faces running parallel to the resonator axis are covered by an electrically insulating passivation, and
on a side of the passivation facing away from the semiconductor body a cooling layer is arranged, which is configured to dissipate at least part of the power loss generated in the semiconductor body during operation.

An optoelectronic semiconductor laser component described herein is based on the following considerations, among others: In future optoelectronic semiconductor components, ever smaller dimensions will be sought. For example, higher pixel densities of display systems can be achieved. Decreasing dimensions of semiconductor components are associated with an increase in the density of electrical contacts. This is accompanied by narrower distances between contacts, which makes cooling the optoelectronic semiconductor components increasingly complex.

The optoelectronic semiconductor laser component described herein makes use, among other things, of the idea of providing side faces of a semiconductor body of the optoelectronic semiconductor component with a passivation. The passivation is followed by a cooling layer, which enables further improved cooling of the semiconductor body. Furthermore, a stacked arrangement of several optoelectronic semiconductor components in an optoelectronic module is possible. An improved dissipation of heat from the optoelectronic semiconductor components can be achieved by means of a heat spreading element arranged between the optoelectronic semiconductor components.

According to at least one embodiment of the optoelectronic semiconductor component, the resonator axis is oriented parallel to the mounting side. In particular, the resonator axis is oriented transverse to the stacking direction of the semiconductor body. The optoelectronic semiconductor component is, for example, an edge-emitting component or a horizontal cavity surface emitting laser component (HCSEL).

According to at least one embodiment of the optoelectronic semiconductor component, a first connection structure is arranged on the mounting side, which electrically contacts the first region. The first connection structure is formed with a metal, for example.

According to at least one embodiment of the optoelectronic semiconductor component, a second connection structure is arranged on the mounting side, which electrically contacts the second region. The second connection structure is formed with a metal, for example. In particular, the first and second connection structures are formed with the same material.

According to at least one embodiment of the optoelectronic semiconductor component, the semiconductor body has a waveguide and an insulation region, wherein an electrical contacting of the second region takes place exclusively via the waveguide. In particular, the second connection structure forms a strip-shaped waveguide that makes electrical contact with the second region along a strip. In particular, the waveguide runs parallel to the resonator axis.

The waveguide is preferably formed with an epitaxial material from the material system of the semiconductor body. Preferably, the insulation region is formed with a dielectric, in particular aluminum nitride. The lateral expansion of the waveguide can be used to specifically influence a local current impression in the second region.

According to at least one embodiment of the optoelectronic semiconductor component, the waveguide is congruent with the active region in a plan view of the optoelectronic semiconductor component. In other words, the lateral extent of the active region corresponds to the lateral extent of the waveguide. As a result, a laterally limited emission area can be generated in the semiconductor body. The top view is to be understood as a view from a direction parallel to the stacking direction of the semiconductor body.

According to at least one embodiment of the optoelectronic semiconductor component, the second region has a p-type conductivity and the first region has an n-type conductivity. Preferably, a side of the second region facing away from the first region forms the mounting side. The semiconductor body is therefore mounted “p-down” on a carrier. This enables particularly efficient contacting and cooling of the semiconductor body.

According to at least one embodiment of the optoelectronic semiconductor component, the passivation is arranged on the side of the semiconductor body facing away from the mounting side. Advantageously, the semiconductor body can thus be particularly well protected from external environmental influences. In particular, the side of the semiconductor body facing away from the mounting side is completely covered by the passivation.

According to at least one embodiment of the optoelectronic semiconductor component, a via penetrates the second region completely and contacts the first region electrically. For example, the via is formed with a metal. In particular, the via is electrically insulated from the second region. Advantageously, the first region can be contacted from the mounting side.

According to at least one embodiment of the optoelectronic semiconductor component, the cooling layer is formed with an electrically conductive material. For example, the cooling layer is formed with a galvanically deposited metal. By means of a galvanically deposited cooling layer, a particularly good overmolding of the passivation and the semiconductor body can be advantageously achieved. Preferably, the cooling layer is formed from a metal or a metal alloy or consists of a metal or a metal alloy.

According to at least one embodiment of the optoelectronic semiconductor component, the first region is electrically contacted by the cooling layer. Advantageously, this eliminates the need for a further first connection structure. In particular, the cooling layer has an electrical and a thermal contact to the first region.

According to at least one embodiment of the optoelectronic semiconductor component, the optical resonator is delimited by an output coupling facet and an end facet. By means of the output coupling facet, part of the electromagnetic radiation generated in the active region is coupled out from the semiconductor body. The end facet is preferably arranged on a side face of the semiconductor body opposite the output coupling facet. The end facet has a higher optical reflectivity for the electromagnetic radiation generated in the active region than the output coupling facet.

According to at least one embodiment of the optoelectronic semiconductor component, the passivation is arranged on the end facet. In particular, the end facet is completely covered by the passivation. Covering the end facet with the passivation can enable additional cooling of the end facet. The output coupling facet is advantageously free of the passivation in order to achieve undisturbed emission of electromagnetic radiation.

According to at least one embodiment of the optoelectronic semiconductor component, the output coupling facet is oriented transverse to the mounting side. In other words, the output coupling facet is a side face of the semiconductor body. The semiconductor component designed in this way is therefore edge-emitting. Edge-emitting semiconductor components can be stacked on top of each other particularly easily to form a larger module.

According to at least one embodiment of the optoelectronic semiconductor component, the output coupling facet is aligned parallel to the mounting side. The semiconductor component produced in this way is a HCSEL. For example, a plurality of HCSEL components can be arranged next to each other in an arrangement.

According to at least one embodiment of the optoelectronic semiconductor component, the semiconductor body does not have a growth substrate. For example, a growth substrate of the semiconductor body is removed from the semiconductor body in a previous step of a manufacturing process. Advantageously, this enables improved electrical and thermal contacting of the semiconductor body, as the thermal and electrical resistance of the growth substrate is eliminated.

According to at least one embodiment of the optoelectronic semiconductor component, an electrical connection is made exclusively via the mounting side. In other words, the first and second connection structures are arranged on the mounting side. This enables simplified contacting of the first region and the second region. A side of the semiconductor body opposite the mounting side can thus advantageously remain free of connection structures and thus be used for cooling.

An optoelectronic module is further disclosed. In particular, the optoelectronic module comprises an optoelectronic semiconductor component described herein. That is, all features disclosed in connection with the optoelectronic semiconductor component are also disclosed for the optoelectronic module and vice versa.

According to at least one embodiment, the optoelectronic module comprises at least two optoelectronic semiconductor components, wherein the resonator axes of the optoelectronic semiconductor components are oriented parallel to each other and a heat spreading element is arranged between each two optoelectronic semiconductor components. In other words, the optoelectronic semiconductor components are stacked on top of one another and are each separated from one another by a heat spreading element. For example, an optoelectronic semiconductor component is in direct contact with the heat spreading element. An advantageously increased density of components can be achieved by such a stacked arrangement of the optoelectronic semiconductor components.

According to at least one embodiment of the optoelectronic module, the heat spreading element has an anisotropic thermal conductivity, with the thermal conductivity being higher parallel to the mounting side of the semiconductor bodies than in a direction transverse thereto. Such anisotropic head conductivity enables particularly efficient dissipation of heat from the optoelectronic semiconductor components.

According to at least one embodiment of the optoelectronic module, the heat spreading element comprises electrical connection lines. For example, the electrical connection lines are arranged on a surface of the heat spreading element or are at least partially embedded in the heat spreading element. This makes it particularly easy to make electrical contact with the optoelectronic semiconductor components.

According to at least one embodiment of the optoelectronic module, the heat spreading element is formed with graphene. Graphene has a particularly advantageous anisotropic head conductivity.

According to at least one embodiment, the optoelectronic module comprises a shaped body that absorbs and dissipates heat from the heat spreading element. Preferably, the shaped body is formed with one of the following materials: solder, sintering paste, nanowires, thermally conductive polymer. The shaped body is in direct contact with the heat spreading element, for example.

An optoelectronic semiconductor component described herein is particularly suitable for use as a compact laser light source in projection applications, head-up displays, augmented displays or virtual reality displays.

Further advantages and advantageous configurations and further embodiments of the optoelectronic semiconductor component result from the following exemplary embodiments shown in connection with the figures.

### BRIEF DESCRIPTION OF THE DRAWINGS

FIG. 1 a schematic sectional view of an optoelectronic semiconductor component according to a first exemplary embodiment,

FIG. 2A a schematic sectional view of an optoelectronic semiconductor component described herein according to a second exemplary embodiment,

FIG. 2B a schematic sectional view of a semiconductor component described herein according to the second exemplary embodiment,

FIG. 3 a schematic sectional view of an optoelectronic semiconductor component described herein according to a third exemplary embodiment,

FIG. 4 a schematic sectional view of an optoelectronic module described herein according to a first exemplary embodiment,

FIG. 5 a perspective schematic view of an optoelectronic module described herein according to a second exemplary embodiment,

FIG. 6 a schematic sectional view of an optoelectronic semiconductor component described herein according to a fourth exemplary embodiment, and

FIG. 7 a schematic sectional view of an optoelectronic semiconductor component described herein according to a fifth exemplary embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

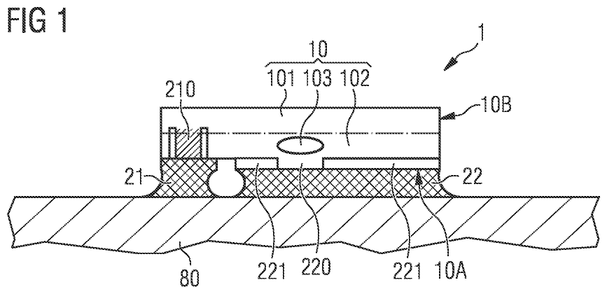

FIG. 1 shows a schematic sectional view of an optoelectronic semiconductor component 1 according to a first exemplary embodiment. The optoelectronic semiconductor component 1 comprises a semiconductor body 10. The semiconductor body 10 is formed with a first region 101 of a first conductivity, a second region 102 of a second conductivity and an active region 103. The active region 103 is configured to generate electromagnetic radiation.

The semiconductor body 10 has a waveguide 220 and an insulation region 221. An electrical connection of the second region 102 is made exclusively in the waveguide 220. The extension of the second connection structure 22 lying next to the waveguide 220 is electrically insulated from the second region 102 by the insulation region 221. For example, the insulation region 221 is formed by a partial coating of the semiconductor body 10 with a dielectric, for example aluminum nitride or gallium nitride. In this way, a current impression can preferably be made in the second region 102 exclusively in a region that is strip-shaped, for example, while advantageously maintaining thermal contact over the entire surface between the second connection structure 22 and the semiconductor body 10.

In a top view of the optoelectronic semiconductor component 1, the waveguide 220 and the active region 103 are congruent. For example, the waveguide 220 is between 1 μm and 45 μm wide, in particular between 1 μm and 5 μm or between 30 μm and 45 μm. Here and in the following, the width is to be understood as a spread of the waveguide 220 transverse to its main direction of extension. A width of the waveguide 220 between 1 μm and 5 μm is advantageous for low power applications, such as augmented reality. A width of the waveguide 220 between 30 μm and 45 μm is particularly advantageous for power lasers in material processing and projection applications.

For example, the active region 103 is a region between the waveguide 220 and the second region 102. The semiconductor body 10 does not include a growth substrate. In other words, the semiconductor body 10 is formed as a thin film chip. The removal of a growth substrate facilitates cooling of the semiconductor body 10, since a thermal resistance of the growth substrate can be omitted.

The semiconductor body 10 has a mounting side 10A and side faces 10B oriented transversely to the mounting side 10A. The mounting side 10A is a main surface of the semiconductor body 10, which is oriented transversely, in particular perpendicularly, to a stacking direction of the semiconductor body 10. Advantageously, the mounting side 10A is configured to be flat within a manufacturing tolerance.

The semiconductor body 10 is mounted on a carrier 80. The carrier 80 is formed, for example, with one of the following materials: aluminum nitride, silicon carbide, silicon. In particular, the carrier 80 is formed with a direct plated copper comprising a silicon carbide with a 30 μm to 50 μm thick layer of copper. A first connection structure 21 and a second connection structure 22 are arranged between the semiconductor body 10 and the carrier 80. The first and second connection structures 21, 22 are formed with one of the following materials: a solder, such as AuSn, InSn, SnCu, SnAgCu a sintering paste, such as Au, Ag, or by a compression bonding method by, for example, AuAu friction welding. The first connection structure 21 is electrically conductively connected to the first region 101 and the second connection structure 22 is electrically conductively connected to the second region 102.

A via 210 extends through the second region 102 and makes electrical contact with the first region 101. The via 210 is electrically contacted by the first connection structure 21. The electrical connection of the semiconductor body 10 is thus made exclusively via the mounting side 10A of the semiconductor body 10. As a result, a side of the semiconductor body 10 opposite the mounting side 10A can be used for cooling the semiconductor body 10.

Preferably, the second connection structure 22 is designed as a p-connection, the second region 102 has a p-conductivity and the first region 101 has an n-conductivity. Consequently, the semiconductor body 10 is contacted exclusively from its “p-side”, while its “n-side” remains free.

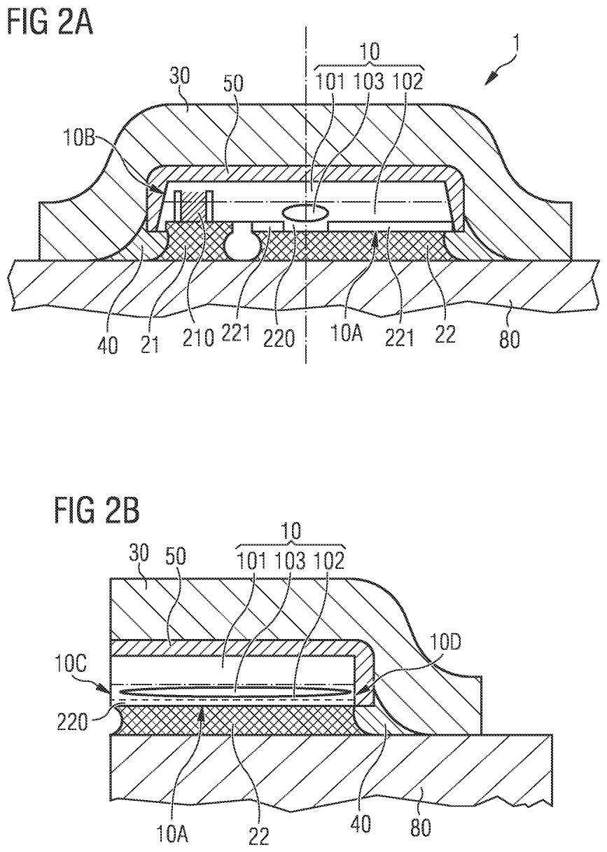

FIG. 2A shows a schematic sectional view of an optoelectronic semiconductor component 1 described herein according to a second exemplary embodiment. The second exemplary embodiment essentially corresponds to the first exemplary embodiment shown in FIG. 1. In contrast to the first exemplary embodiment, the side faces 10B of the semiconductor body 10 are slightly inclined in order to facilitate the application of a passivation 50. The semiconductor body 10 is encapsulated in a circumferentially electrically insulating manner by means of the passivation 50. The side faces 10B of the semiconductor body 10 and a side of the semiconductor body 10 opposite the mounting side 10A are covered by the passivation 50. The passivation 50 is formed with an electrically insulating material, for example a dielectric. Preferably, the passivation 50 is formed with silicon nitride. The passivation 50 also extends, for example, over an end facet 10D of the semiconductor body 10.

On a side of the passivation layer 50 facing away from the semiconductor body 10, a cooling layer 30 is arranged downstream of the passivation layer 50. The cooling layer 30 has a thickness of 30 μm to 50 μm, preferably of 70 μm to 100 μm. The cooling layer 30 is formed, for example, with one of the following materials: solder, copper, silver, thermally conductive polymers. In particular, the cooling layer 30 is deposited using a galvanic deposition method. The semiconductor body 10 is electrically insulated from the cooling layer 30 by means of the passivation 50. The first connection structure 21 and the second connection structure 22 are insulated from the cooling layer 30 by means of an encapsulation mass 40. The encapsulation mass 40 is formed, for example, with an electrically insulating polymer, such as an epoxy resin.

FIG. 2B shows a schematic sectional view of an optoelectronic semiconductor component 1 according to the second exemplary embodiment described herein along an imaginary sectional line along a main extension direction of the waveguide 220 through the waveguide 220 perpendicular to the mounting side 10A. The passivation 50 extends on the side of the semiconductor body 10 opposite the mounting side 10A. Furthermore, the passivation 50 covers an end facet 10D. This advantageously enables particularly good cooling of the end facet 10D. In particular, the end facet 10D has a higher optical reflectivity for the electromagnetic radiation generated in operation in the active region 103 than the output coupling facet 10C. The output coupling facet 10C opposite the end facet 10D is free of the passivation 50 in order to allow electromagnetic radiation to be coupled out from the semiconductor body 10 as unhindered as possible.

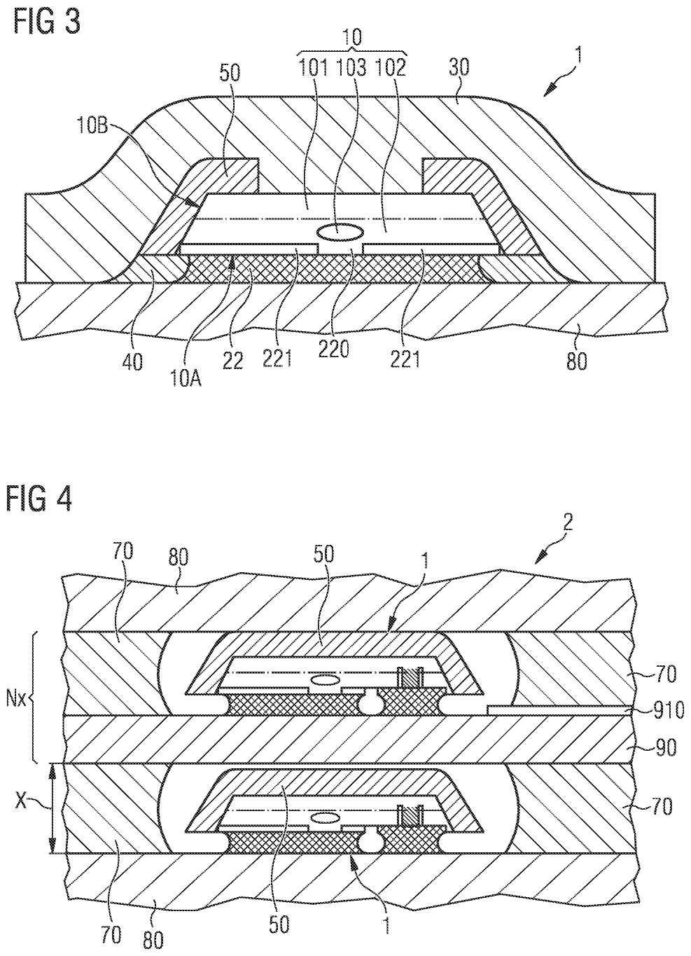

FIG. 3 shows a schematic sectional view of an optoelectronic semiconductor component 1 described herein according to a third exemplary embodiment. The third exemplary embodiment essentially corresponds to the second exemplary embodiment shown in FIG. 2. In contrast to the second exemplary embodiment, the semiconductor body 10 has no via 210 and no first connection structure 21. The cooling layer 30 is formed with an electrically conductive material.

The first region 101 is electrically contacted directly via the cooling layer 30. The passivation 50 is open on a side of the semiconductor body 10 opposite the mounting side 10A in order to enable an electrical connection of the first region 101 to the cooling layer 30. The first region 101 is therefore connected both thermally and electrically to the cooling layer 30. The electrical connection of the second region 102 is made via the second connection structure 22. The passivation 50 is arranged laterally around the semiconductor body 10.

FIG. 4 shows a schematic sectional view of an optoelectronic module 2 described herein according to a first exemplary embodiment. The optoelectronic module 2 comprises two optoelectronic semiconductor components 1 according to the first exemplary embodiment. The optoelectronic semiconductor components 1 are stacked on top of each other and separated from each other by a heat spreading element 90.

The heat spreading element 90 is formed with a material having anisotropic head conductivity. The thermal conductivity of the heat spreading element 90 in a direction transverse to the stacking direction of the optoelectronic semiconductor components 1 is greater than a thermal conductivity of the heat spreading element 90 transverse to this direction. This enables an advantageously efficient dissipation of heat from the optoelectronic semiconductor components 1. For example, the heat spreading element 90 is formed with graphene. In an optoelectronic module two, more than two optoelectronic semiconductor components 1 can also be arranged stacked on top of each other. In particular, a stacked layer of the optoelectronic module 2 comprising an optoelectronic semiconductor component 1 has a vertical height X of 10 μm to 20 μm. Electrical connection lines 910 are arranged on an upper side of the heat spreading element 90. By means of the electrical connection lines 910, the optoelectronic semiconductor components 1 can be electrically connected. The electrical connection lines 910 could also be at least partially embedded in the heat spreading element 90.

The uppermost optoelectronic semiconductor component 1 and the lowermost optoelectronic semiconductor component 1 of the optoelectronic module 2 are each in contact with a carrier 80. A shaped body 70 is arranged between each of the carriers 80 and the heat spreading element 90. The shaped body 70 establishes a thermal contact between the heat spreading element 90 and the carriers 80. For example, the shaped body 70 is formed with one of the following materials: solder, sintering paste, nanowires, thermally conductive polymer.

For example, an optoelectronic module 2 can also be formed with optoelectronic semiconductor components 1 as shown in FIG. 3. A combination of more than two optoelectronic semiconductor components 1, each with different electrical contacts, in an optoelectronic module 2 is also possible.

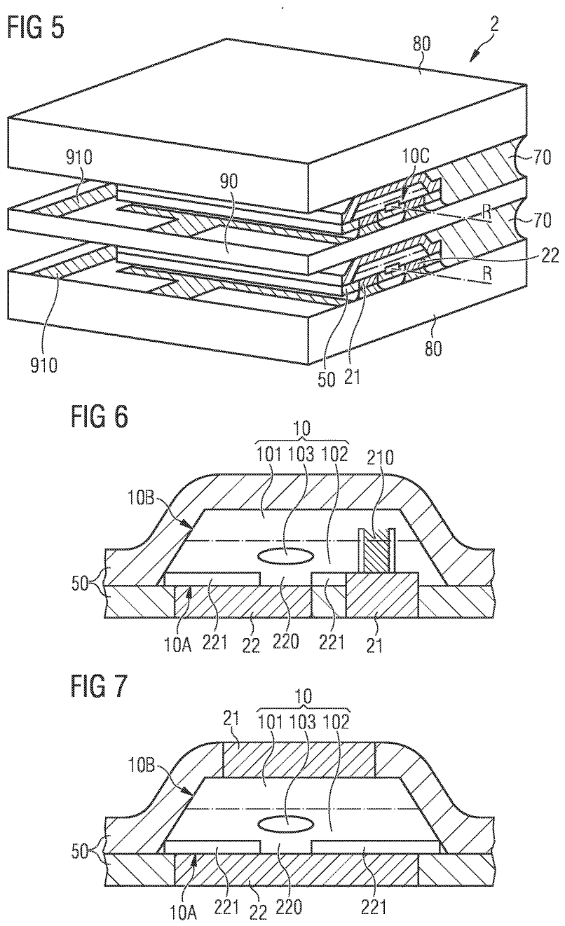

FIG. 5 shows a perspective schematic view of an optoelectronic module 2 described herein according to a second exemplary embodiment. The second exemplary embodiment essentially corresponds to the first exemplary embodiment shown in FIG. 4. In the perspective view of FIG. 5, the resonator axes R and the output coupling facets 10C of the optoelectronic semiconductor components 1 are clearly recognizable. The resonator axes R and the output coupling facets 10C of the optoelectronic semiconductor components 1 are oriented parallel to each other. The end facets 10D of the optoelectronic semiconductor components 1 are arranged on the respective opposite sides of the output coupling facets 10C.

Electrical connection lines 910 for the electrical control of the optoelectronic semiconductor components 1 are arranged on the heat spreading element 90 and a carrier 80. The optoelectronic semiconductor components 1 each comprise a circumferential passivation 50. The output coupling facets 10C of the optoelectronic semiconductor components 1 are each free of the passivation 50 in order to avoid shading.

FIG. 6 shows a schematic sectional view of an optoelectronic semiconductor component 1 described herein according to a fourth exemplary embodiment. The fourth exemplary embodiment essentially corresponds to the second exemplary embodiment shown in FIG. 2. In contrast to the second exemplary embodiment, the first connection structure 21 and the second connection structure 22 are configured to be mechanically supporting. Consequently, a carrier 80 can be dispensed with. The passivation 50 completely covers the semiconductor body 10 with the exception of the output coupling facet 10C. Electrical contact is made exclusively via the mounting side 10A.

FIG. 7 shows a schematic sectional view of an optoelectronic semiconductor component described herein according to a fifth exemplary embodiment. The fifth exemplary embodiment essentially corresponds to the fourth exemplary embodiment shown in FIG. 6. In contrast to the fourth exemplary embodiment, the semiconductor body 10 does not comprise a via 210. The first connection structure 21 is arranged on a side of the semiconductor body 10 opposite the mounting side 10A.

The invention is not limited by the description based on the embodiments. Rather, the invention includes any new feature as well as any combination of features, which includes in particular any combination of features in the patent claims, even if this feature or combination itself is not explicitly stated in the patent claims or exemplary embodiments.

1. An optoelectronic semiconductor component (1) comprising:
a semiconductor body having a first region of a first conductivity, a second region of a second conductivity and an active region which is configured to emit coherent electromagnetic radiation, wherein
the second region has a p-type conductivity and the first region has an n-type conductivity,
an optical resonator is formed in the semiconductor body along a resonator axis,
the semiconductor body has a mounting side and side faces extending transversely to the mounting side,
a side of the second region facing away from the first region forms the mounting side,
side faces extending parallel to the resonator axis are covered by an electrically insulating passivation, and
on a side of the passivation facing away from the semiconductor body a cooling layer is arranged, which is configured to dissipate at least some of the power loss generated in the semiconductor body during operation.

2. The optoelectronic semiconductor component according to claim 1, in which the resonator axis is aligned parallel to the mounting side.

3. The optoelectronic semiconductor component according to claim 1, in which a first connection structure is arranged on the mounting side, which contacts the first region electrically.

4. The optoelectronic semiconductor component according to claim 1, in which a second connection structure is arranged on the mounting side, which contacts the second region electrically.

5. The optoelectronic semiconductor component according to claim 4, in which the semiconductor body has a waveguide and an insulation region, wherein an electrical contacting of the second region is made exclusively via the waveguide.

6. The optoelectronic semiconductor component according to claim 5, in which the lateral extension of the waveguide is congruent with the active region.

7. The optoelectronic semiconductor component according to claim 1, where the electrical connection is made exclusively via the mounting side.

8. (canceled)

9. The optoelectronic semiconductor component according to claim 1, in which a via completely penetrates the second region and electrically contacts the first region.

10. The optoelectronic semiconductor component according to claim 1, in which the cooling layer is formed with an electrically conductive material.

11. The optoelectronic semiconductor component according to claim 10, in which the first region is electrically contacted by the cooling layer.

12. The optoelectronic semiconductor component according to claim 1, in which the optical resonator is delimited by an output coupling facet and an end facet.

13. The optoelectronic semiconductor component according to claim 12, in which the passivation is arranged on the end facet.

14. The optoelectronic semiconductor component according to claim 12, in which the output coupling facet is oriented transversely to the mounting side.

15. The optoelectronic semiconductor component according to claim 12, in which the output coupling facet is oriented parallel to the mounting side.

16. An optoelectronic module comprising at least two optoelectronic semiconductor components according to claim 1, wherein
the resonator axes of the optoelectronic semiconductor components are oriented parallel to each other, and
a heat spreading element is arranged between each two optoelectronic semiconductor components.

17. The optoelectronic module according to claim 16, in which the heat spreading element has an anisotropic head conductivity, the thermal conductivity being higher parallel to the mounting side of the semiconductor body than in a direction transverse thereto.

18. The optoelectronic module according to claim 16, in which the heat spreading element comprises electrical connection lines.

19. The optoelectronic module according to claim 16, in which the heat spreading element is formed with graphene.

20. The optoelectronic module according to claim 16, in which the module comprises a shaped body which absorbs and dissipates heat from the heat spreading element.

21. An optoelectronic semiconductor component comprising:
a semiconductor body having a first region of a first conductivity, a second region of a second conductivity, and an active region which is configured to emit coherent electromagnetic radiation, wherein
the second region has a p-type conductivity and the first region has an n-type conductivity,
an optical resonator is formed in the semiconductor body along a resonator axis,
the semiconductor body has a mounting side and side faces extending transversely to the mounting side,
a side of the second region facing away from the first region forms the mounting side,
side faces extending parallel to the resonator axis are covered by an electrically insulating passivation,
the passivation is arranged on the side of the semiconductor body facing away from the mounting side, and
on a side of the passivation facing away from the semiconductor body a cooling layer is arranged, which is configured to dissipate at least some of the power loss generated in the semiconductor body during operation.
